(19) United States
(12) Patent Application Publication
(10) Pub. No.: US 2006/0211171 A1
(43) Pub. Date: Sep. 21, 2006

(54) Underfill on substrate process and ultra-fine pitch, low standoff chip-to-package interconnections produced thereby

(76) Inventors: Rao O. Tummala, Stone Mountain, GA (US); Verkatesh Sundaram, Norcross, GA (US); Jui-Yun Tsai, Atlanta, GA (US); Ching Ping Wong, Berkeley Lake, GA (US)

Correspondence Address: Law Offices of Kenneth W. Float, 2095 Hwy. 211 NW, #2F, Braselton, GA, 30517, US

(21) Appl. No.: 11/372,640

(22) Filed: Mar. 10, 2006

Related U.S. Application Data
(60) Provisional application No. 60/663,135, filed on Mar. 18, 2005.

(51) Int. Cl. H01L 21/00

(52) U.S. Cl. 438/108

(57) ABSTRACT

Disclosed are methods and substrates suitable for flip-chip assembly. Underfill processing used to produce the substrates provides for lead-free, eutectic solder, and other alloy reflow based flip-chip interconnects for 10-20 μm peripheral and area array I/O pitch. The methods and substrates utilize underfill materials with tailored properties along with a variety of patterning techniques to produce openings in underfill material disposed on the substrates that are used as an alignment guide for flip-chip attachment to the substrates.

### BACKGROUND

The present invention relates generally to flip-chip fabrication methods and substrates suitable for flip-chip assembly.

The most popular approach to flip-chip integrated circuit (IC) assembly is to use lead-free or eutectic Pb/Sn solder, placing the IC on the substrate, reflowing the solder joints at high temperature, and finally dispensing and curing “capillary flow” underfill material to improve the interconnect reliability. Another approach involves “no-flow” underfill dispensing on the substrate, placing a bare IC on the substrate, using moderate pressure to push the underfill out of substrate bond pads, followed by simultaneous solder reflow and underfill cure. A leading edge flip-chip process in manufacturing is around 150-180 μm area array and 50 μm pitch peripheral with 100-125 μm pitch area array and 20-50 μm pitch peripheral flip-chip in R&D around the world. Both of the approaches described above have severe technical limitations for future systems with <50 μm pitch flip-chip interconnection. The driver for such a reduction in pitch is two-fold; higher I/O density on the IC due to the higher transistor density, and lower stand-off height interconnects to reduce electrical parasitics and enable higher signal speed and bandwidth.

The critical property requirements for underfill materials for such fine-pitch interconnects are low coefficient of thermal expansion (CTE) close to that of the solder used for reflow, and high elastic modulus (8-10 GPa) to absorb strains induced by CTE mismatch between chip and substrate. The current approach of capillary flow underfill is limited by flow properties of the polymer based underfill materials which use a high volume of ceramic fillers to reduce the coefficient of thermal expansion. The no-flow approach also has limitations of being able to clear the bond pads of underfill material that is highly filled for low CTE and high modulus.

It would be desirable to have a flip-chip fabrication method that improves upon the conventional approaches described above. It would also be desirable to provide the ability to select any underfill material with appropriate CTE, modulus and other properties without being restricted by the viscosity and flow characteristics of the underfill and its ability to fill very small chip-to-substrate gap heights.

### BRIEF DESCRIPTION OF THE DRAWINGS

The various features and advantages of the present invention may be more readily understood with reference to the following detailed description taken in conjunction with the accompanying drawings, wherein like reference numerals designate like structural elements, and in which:

FIG. 1 illustrates an exemplary underfill process using laser patterning;

FIG. 2 illustrates an exemplary underfill process using photolithographic patterning;

FIG. 3 illustrates an exemplary flip-chip assembly process employing substrates prepared using the processes illustrated in FIGS. 1 and 2; and

FIG. 4 illustrates another exemplary flip-chip assembly process.

### DETAILED DESCRIPTION

Disclosed herein is a novel approach to interconnect assembly and underfill processing applicable to standard lead-free, eutectic solder, and other alloy reflow based flip-chip interconnects, copper, nickel or other metal/alloy pillar or column interconnects, gold stud bump connections (bonded using gold-to-gold thermosonic bonding), conductive polymer bumps (bonded using a reflow process), composite post flexible interconnects, and all other interconnect types for low stand-off chip to package interconnects in the 10-100 μm peripheral and area array I/O pitch. The approach and processes disclosed herein utilize underfill materials with tailored properties along with a variety of patterning techniques to produce openings in underfill material disposed on a substrate that are used as an alignment guide for flip-chip attachment to the substrate. For example, openings in the underfill materials may be achieved using laser patterning, photolithographic patterning, stamping, imprinting, plasma etching, dry etching, or wet chemical etching, for example. The disclosed process methods are also relevant to package substrates with embedded ICs buried in the core or build-up layers wherein the interconnection from chip to substrate is formed using any of the techniques listed above.

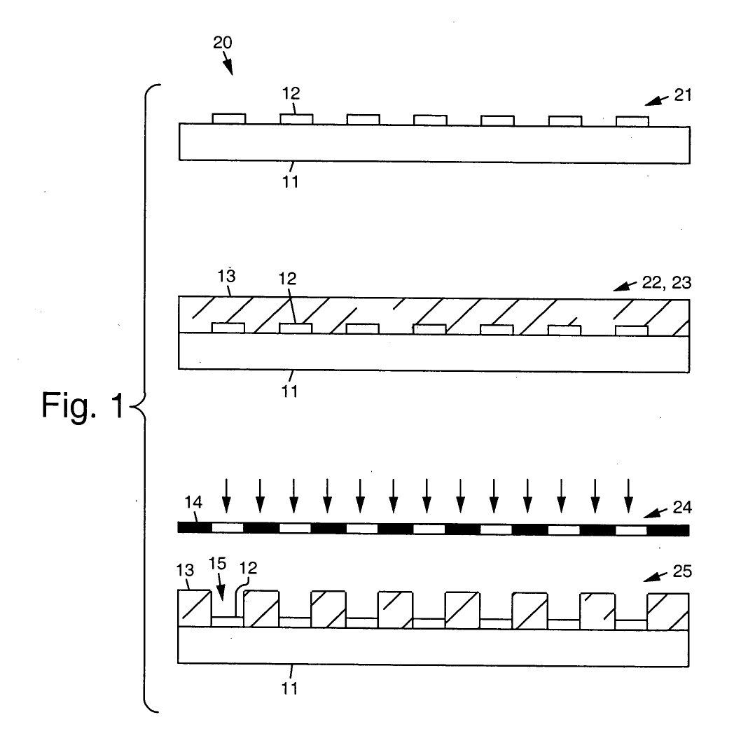

Referring now to the drawing figures, FIG. 1 illustrates an exemplary laser underfill process 20 using laser patterning. As is shown in FIG. 1, in this first process 20, bond pads 12 (I/O pads 12) are formed 21 on a substrate 11. An underfill material 13 is deposited 22 on top of the substrate 11 and partially cured 23. A mask 14 is applied 24 to the partially cured substrate 11. The partially cured substrate 11 is then laser patterned 25 through the mask 14 to produce a plurality of openings 15 in the underfill material 13 that expose the bond pads 12.

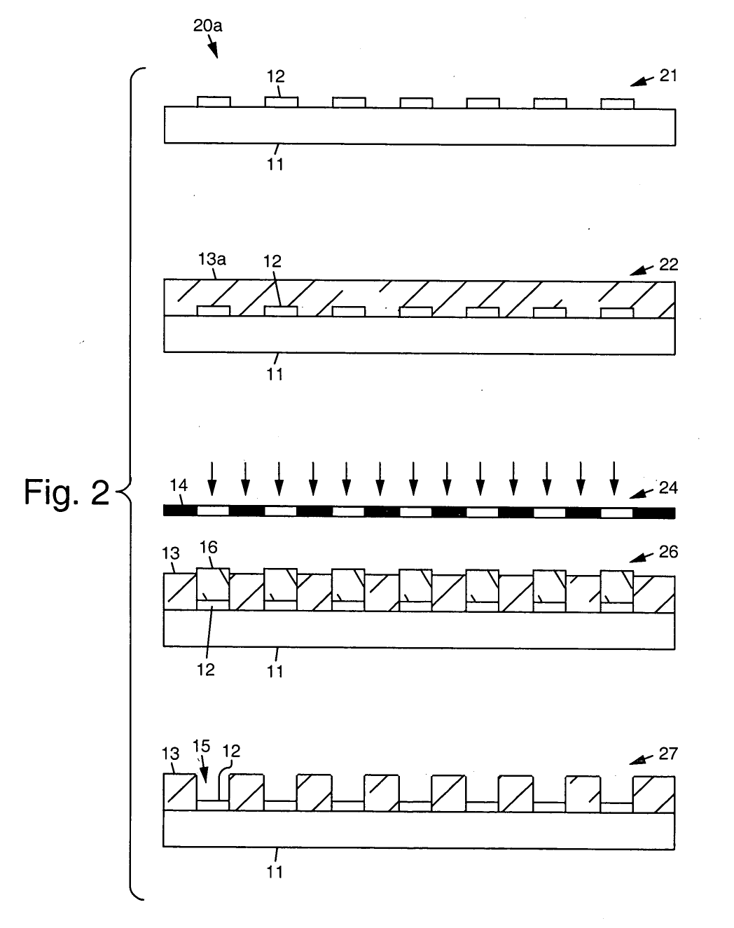

FIG. 2 illustrates an exemplary underfill process 20a using photolithographic patterning. As is shown in FIG. 2, in this second process 20a, bond pads 12 are formed 21 on a substrate 11. A photo underfill material 13a is then deposited 22 on top of the substrate 11. A mask 14 is applied 24 to the substrate 11. The substrate 11 is then exposed 26 with ultraviolet (UV) radiation through the mask 14. The UV exposed substrate 11 is then developed 26 to produce a plurality of openings 15 in the underfill material 13 that expose the bond pads 12.

More particularly, in the processes 20, 20a illustrated in FIGS. 1 and 2, the underfill material 13 (composite of polymer and ceramic) is deposited 22 on a fabricated substrate 11 that has bond pads 12 formed thereon. This may be accomplished using commonly used processes such as spin coating, meniscus/roller coating or curtain coating, or a lamination process in the case of dry film materials. Once the underfill material 13 is deposited, the bond pad sites are opened by patterning 25, 26 the underfill material using laser ablation (FIG. 1), UV lithography (FIG. 2), or a plasma/chemical process, for example. Alternatively, methods such as stamping and imprinting may be used to precisely define openings 15 in the underfill material 13 for the I/O pads 12 on the substrate 11. At this point in the processes 20, 20a, the underfill material 13 is in a partially cured or “B-stage” state and may be made to reflow and fully cure during assembly. An option for this process is to use a filled thermoplastic underfill material 13 that can soften and reflow around the solder joints during assembly.

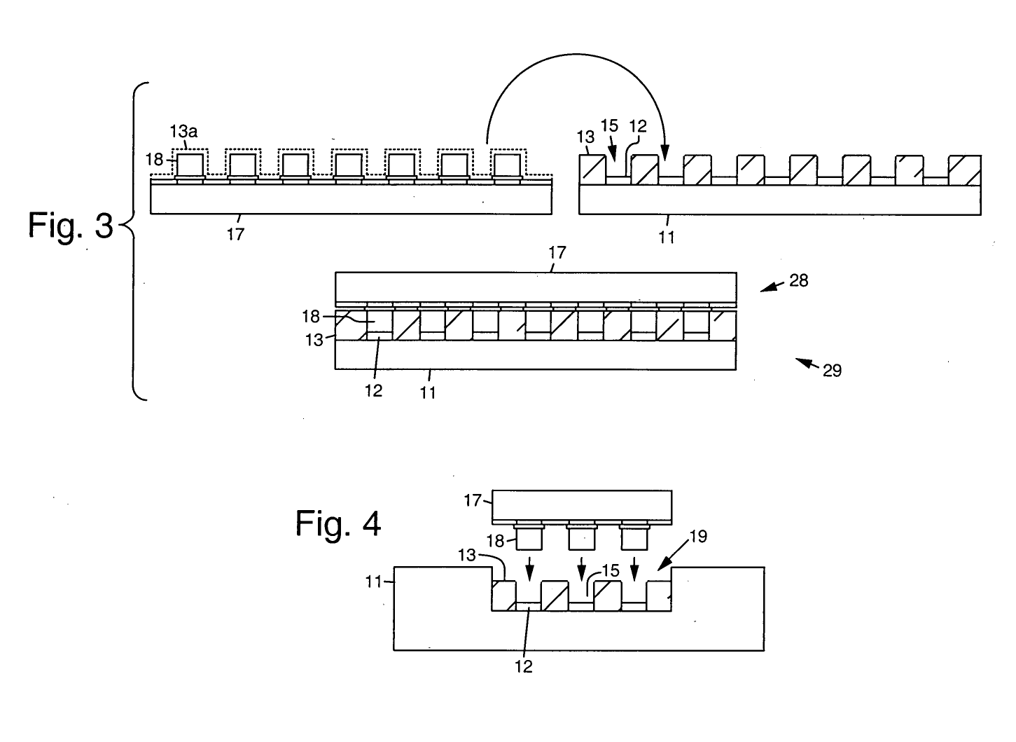

FIG. 3 illustrates an exemplary flip-chip assembly process employing substrates prepared using the processes 20, 20a described above and illustrated in FIGS. 1 and 2. A solder bumped 18 (or other type interconnected) bare die integrated circuit (IC) 17 is placed (flipped) 28 (illustrated by the semicircular arrow in FIG. 3) onto the substrate 11 previously processed in the manner described with reference to FIGS. 1 and 2. The openings 15 in the underfill material 13 act as a guide for the assembly, making alignment for fine pitch flip-chip easier. The final step in the processes 20, 20a is a thermal treatment 29 that accomplishes simultaneous curing of the underfill material 13 and solder (bump 18) reflow to ensure contact with the bond pads 12.

One novel aspect of the disclosed processes 20, 20a is the ability to use underfill materials 13 with tailored properties, because the viscosity of the underfill material 13 is not critical for dispensing (compared to current capillary flow processes) and flow of underfill material 13 during chip placement 28 is not critical (compared to current no-flow processes). The photolithographic or laser patterning processes 20, 20a also allows for extremely fine pitch without the problems of dispensing underfill material 13 into the tight space between I/O bumps common to conventional practices. The templated underfill material 13 on the substrate 11 also acts an alignment guide for chip placement 28 enabling low cost equipment to be used for 10-20 μm pitch flip-chip assembly.

One of the potential issues encountered during early work on these processes 20, 20a was the effect of photolithographic or laser patterning on the “degree of cure” of the underfill material 13 that could affect the flow of the underfill material 13 during final solder reflow. A novel approach was developed to solve this potential problem. The underfill material 13 deposited on the substrate 11 may be fully cured prior to patterning as is common in “microvia” substrates today. However, an additional thin layer of underfill material 13a (illustrated in dashed lines in FIG. 3) may be coated on the bumped wafer 17 and partially cured (B-staged). This partially cured layer acts as a bonding layer to the fully cured underfill material 13 on the substrate 11 during final reflow in assembly.

FIG. 4 illustrates another exemplary flip-chip assembly process. This exemplary flip-chip assembly process embodies substantially similar processing steps as have been described above, but in this case, the substrate 11 has a cavity 19 formed therein. The cavity 19 has a plurality of bond pads 12 (I/O pads 12) formed 21 therein. A solder bumped 18 (or other type interconnected) bare die integrated circuit (IC) 17 is placed (flipped) so that it is inserted within the confines of the cavity 19 and is attached to the bond pads 12. This flip-chip structure has a lower overall height than conventional flip-chip structures such as is shown in FIG. 3. In the exemplary flip-chip assembly process shown in FIG. 4, the underfill material 13 may be deposited within the confines of the cavity 19, or may be deposited on the entire surface of the substrate 11 including the cavity 19.

Thus, flip-chip fabrication methods employing laser and photolithographic underfill patterning processes have been disclosed. It is to be understood that the above-described embodiments are merely illustrative of some of the many specific embodiments that represent applications of the principles discussed above. Clearly, numerous and other arrangements can be readily devised by those skilled in the art without departing from the scope of the invention.

What is claimed is:

1. A flip-chip fabrication method comprising:
providing a substrate;
forming bond pads on the substrate;
depositing an underfill material on top of the substrate;
partially curing the underfill material;
forming openings in the partially cured underfill material on the substrate to expose the bond pads;
placing an integrated circuit having bonding interconnects on top of the substrate so as to align the bonding interconnects on the integrated circuit with the openings in the partially cured underfill material on the substrate; and
thermally processing the integrated circuit and substrate with partially cured underfill material to fully cure the underfill material and reflow the bonding interconnects to ensure contact with the bond pads.

2. The method recited in claim 1 wherein forming openings in the partially cured underfill material on the substrate is achieved by laser patterning, photolithographic patterning, stamping, imprinting, plasma etching, dry etching, or wet chemical etching.

3. The method recited in claim 1 wherein the underfill material comprises a composite of polymer and ceramic.

4. The method recited in claim 1 wherein the underfill material is deposited using spin coating, meniscus/roller coating, curtain coating, or lamination.

5. The method recited in claim 1 wherein the underfill material comprises a filled thermoplastic material.

6. The method recited in claim 1 wherein the underfill material on the substrate is fully cured prior to patterning, underfill material is deposited on solder interconnects of the integrated circuit and partially cured prior to its placement on top of the substrate.

7. The method recited in claim 1 wherein the interconnects between the integrated circuit and substrate comprise a metal/alloy post/pillar/column interconnects fabricated on the integrated circuit that are bonded to the substrate using a low melting temperature bonding layer or anisotropic/isotropic conductive adhesive applied to the interconnects on the integrated circuit or to the-bond pads.

8. The method recited in claim 1 wherein the interconnects between the integrated circuit and substrate comprise gold stud bumps on the integrated circuit that are bonded to the substrate using gold-to-gold thermosonic bonding.

9. The method recited in claim 1 wherein the interconnects between the integrated circuit and substrate comprise conductive polymer interconnects on the integrated circuit that can be bonded to the substrate using a reflow process.

10. The method recited in claim 1 wherein the substrate comprises a cavity having the bond pads formed therein.

11. The method recited in claim 10 wherein the underfill material is deposited within the confines of the cavity.

12. The method recited in claim 10 wherein the underfill material is deposited on the entire surface of the substrate including the cavity.

13. A flip-chip fabrication method comprising:
providing a substrate;
forming bond pads on the substrate;
depositing an underfill material on top of the substrate;
fully curing at least a portion of the underfill material;
forming openings in the underfill material on the substrate to expose the bond pads;
depositing an additional layer of uniderfill material on an integrated circuit;
placing the integrated circuit having bonding interconnects and additional layer of underfill material on top of the substrate so as to align the bonding interconnects on the integrated circuit with the openings in the underfill material on the substrate; and
thermally processing the integrated circuit and substrate with underfill material to fully cure the additional layer of underfill material and reflow the bonding interconnects and additional layer of underfill material to ensure contact with the bond pads.

14. The method recited in claim 13 wherein forming openings in the partially cured substrate is achieved by laser patterning, photolithographic patterning, stamping or imprinting, plasma or other dry etching, or by wet chemical etching.

15. The method recited in claim 13 wherein the underfill material comprises a composite of polymer and ceramic.

16. The method recited in claim 13 wherein the wherein the underfill material is deposited using spin coating, meniscus/roller coating, curtain coating, or lamination.

17. The method recited in claim 13 wherein the underfill material comprises a filled thermoplastic material.

18. The method recited in claim 1 wherein the substrate comprises a cavity having the bond pads formed therein.

19. The method recited in claim 10 wherein the underfill material is deposited within the confines of the cavity.

20. The method recited in claim 10 wherein the underfill material is deposited on the entire surface of the substrate including the cavity.
